(19) United States
(12) Patent Application Publication
(10) Pub. No.: US 2008/0124920 A1
(43) Pub. Date: May 29, 2008

(54) Fabrication method for an integrated circuit structure

(76) Inventors: Clemens Fitz, Dresden (DE); Axel Buerke, Dresden (DE); Jens Hahn, Dresden (DE); Frank Jakubowski, Dresden (DE); Tobias Mono, Dresden (DE); Joern Regul, Egmating (DE); Sven Schmidbauer, Dresden (DE)

Correspondence Address: JENKINS, WILSON, TAYLOR & HUNT, P. A., 3100 TOWER BLVD., Suite 1200, DURHAM, NC, 27707, US

(21) Appl. No.: 11/985,067

(22) Filed: Nov. 13, 2007

(30) Foreign Application Priority Data
Nov. 15, 2006 (DE) 102006053930.3

(51) Int. Cl. H01L 21/44

(52) U.S. Cl. 438/653; 257/E21.476

(57) ABSTRACT

The present invention provides a fabrication method for an integrated circuit structure comprising the steps of forming a electrode layer stack (5, 6′, 7′, 8′) by sequentially depositing a polysilicon layer (5) on a gate dielectric layer (9); a contact layer (6′) composed of Ti on the polysilicon layer (5); a barrier layer (7′) composed of WN on the contact layer (6′); and a metal layer (8′) composed of W on the barrier layer (7′); wherein steps iii) and iv) are carried out as PVD steps using krypton and/or xenon as sputtering gas; and annealing the layer stack (5, 6′, 7′, 8′) in a thermal step in the temperature range of between 600 and 950° C.

The present invention relates to a fabrication method for an integrated circuit structure.

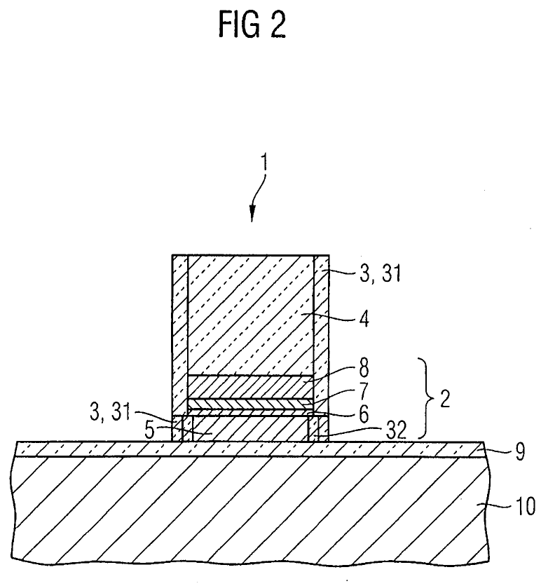

FIG. 2 shows a schematic illustration for elucidating a method for fabricating a transistor gate structure that is known from DE 10 2004 004 864 A1.

In order to fabricate the transistor gate structure 1 illustrated in FIG. 2, a gate electrode layer stack 2 is patterned on a gate dielectric layer 9 provided on a semiconductor substrate 10. The gate electrode layer stack 2 contains a doped polysilicon layer 5 arranged on the gate dielectric layer 9.

A contact layer 6 is provided on the polysilicon layer 5 and a barrier layer 7 is provided on the contact layer 6. The contact layer 6 comprises titanium, and the barrier layer 7 comprises titanium nitride. The gate metal layer 8 is applied on the barrier layer 7. The gate metal layer 8 comprises tungsten (W). An insulating cap 4, preferably composed of silicon nitride, is provided on the gate metal layer 8. Insulating layers 3, which comprise a spacer nitride 31 and a sidewall oxide 32, are situated on the sidewalls of the gate electrode layer stack 2 and the insulating cap 4.

The contact layer 6 completely covers the polysilicon layer 5, and thus prevents an interaction between nitrogen contained in the barrier layer 7 and the silicon of the polysilicon layer 5. In other words, the formation of silicon nitride, which would increase a contact resistance between the gate metal layer 8 and the polysilicon layer 5, is prevented.

In the known fabrication method for a transistor gate structure, the layers 5, 6, 7, 8 are deposited successively and are subsequently patterned by means of known photolithographic techniques. After the patterning, the insulation cap 4 and the insulating layers 3 are provided.

The contact layer 6 can be applied by means of a PVD, CVD or ALD method. During the application of the contact layer 6 it is important that, in the case of a CVD or PVD deposition, for example, the contact layer 6 is applied with exclusion of oxygen. Afterward, the barrier layer 7 can be deposited in the same method after the application of the contact layer 6 in situ in the same installation.

The barrier layer 7, which comprises titanium nitride in the known transistor gate structure, fixedly binds the nitrogen contained even at high temperatures, such that no decomposition of the barrier layer 7 takes place.

The gate metal layer 8 can likewise be deposited in a CVD or PVD method. A penetration of metal from the gate metal layer 8 into the polysilicon layer 5 is prevented by the barrier layer 7.

It has been found that when the layers 6, 7, 8 are deposited in a PVD method using argon as sputtering gas, an annealing step after the deposition of the layer 8 under a forming gas atmosphere brings about a lowering of resistance of the order of magnitude of 30%.

It is an object of the present invention to provide a fabrication method for an integrated circuit structure, wherein the resistance can be lowered further.

According to the invention, this problem is solved by means of the fabrication method specified in claim 1.

The idea on which the present invention is based consists in applying the barrier layer and the metal layer by sputtering using krypton and/or xenon as noble gas instead of argon.

A significant advantage of the method according to the invention is that a lowering of resistance of up to approximately 50% can be obtained when using krypton or xenon as sputtering gas, that is to say that the resistance can be almost halved in comparison with the known method.

Advantageous developments and improvements of the subject matter of the invention are found in the subclaims.

In accordance with one preferred development, the layer stack is a gate electrode layer stack.

In accordance with a further preferred development, steps iii) and iv) are carried out in situ, wherein in step iii) nitrogen is used as sputtering gas in addition to krypton and/or xenon.

In accordance with a further preferred development, the layer stack is patterned prior to annealing.

In accordance with a further preferred development, the annealing is carried out using an argon/hydrogen mixture instead of forming gas.

In accordance with a further preferred development, a lowering of the resistance of the transistor gate structure of between 35 and 55% is obtained by the annealing.

In accordance with a further preferred development, step ii) is carried out as a PVD step using argon as sputtering gas.

In accordance with a further preferred development, an insulation cap and insulating sidewall layers are formed prior to annealing.

In accordance with a further preferred development, the contact layer composed of Ti is converted into a TiN layer during annealing.

An exemplary embodiment of the invention is illustrated in the drawings and is explained in more detail in the description below.

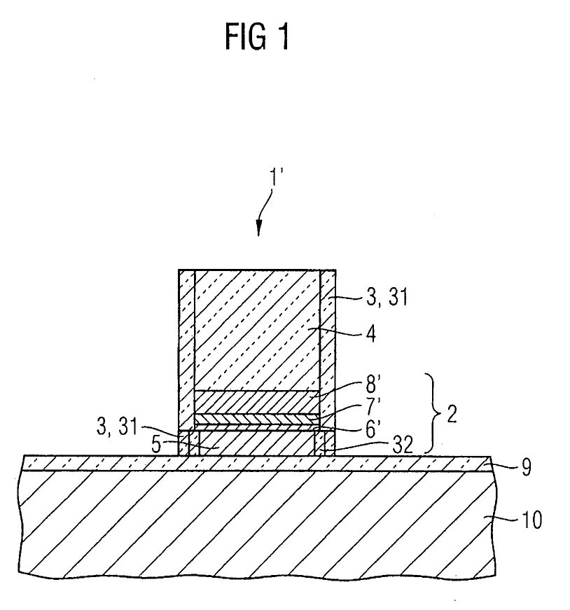

FIG. 1 shows a schematic illustration for elucidating a method for fabricating an integrated circuit structure in form of a transistor gate structure as an embodiment of the present invention; and

FIG. 2 shows a schematic illustration for elucidating a method for fabricating an integrated circuit structure in form of a transistor gate structure that is known from DE 10 2004 004 864 A1.

In the figures, identical reference symbols designate identical or functionally identical component parts.

FIG. 1 shows a schematic illustration for elucidating a method for fabricating an integrated circuit structure in form of a transistor gate structure as an embodiment of the present invention.

In order to fabricate the transistor gate structure 1′ in accordance with the embodiment of the present invention, as in the case of the known transistor gate structure described above, a P- or N-doped polysilicon layer 5 is fabricated on a gate dielectric layer provided on a semiconductor substrate 10. A contact layer 6′ composed of Ti or TiN is subsequently deposited on the polysilicon layer 5 in a PVD method using argon as sputtering gas.

Afterward, the wafer with the semiconductor structure thus produced is transferred into a second process chamber. In the second process chamber, likewise by means of a PVD method, firstly the barrier layer 7′ composed of WN is deposited and then the gate metal layer 8′ composed of W is deposited. In this case, the deposition of the barrier layer 7′ composed of WN takes place using nitrogen gas and krypton gas (alternatively nitrogen gas and xenon gas). For the deposition of the gate metal layer 8′ composed of W, the flow of nitrogen gas is just reduced to zero in situ.

In this example, the thickness of the contact layer 6′ composed of Ti is 3 nm, the thickness of the barrier layer 7′ composed of WN is 7 nm and the thickness of the gate metal layer 8′ is 33 nm.

Afterward, the silicon nitride layer for the insulating cap 4 is provided and the layers 5, 6′, 7′, 8′, 4 are patterned in a known photolithography/etching step. The insulating layers 3 comprising a spacer nitride 31 and a sidewall oxide 32 are subsequently provided on the flanks of the transistor gate structure in known method steps.

It has advantageously been found that the resistance of a transistor gate structure fabricated in this way, when carrying out an annealing step with temperatures of the order of magnitude of 600-950° C., can be reduced by up to about 50%.

The use of krypton or xenon as sputtering gas evidently enables a more advantageous restructuring of the crystal lattices of the layers 6′, 7′, 8′, such that said appreciable reduction of resistance of the order of magnitude of 50% can be obtained.

Although the present invention has been described above on the basis of preferred exemplary embodiments, it is not restricted thereto, but rather can be modified in diverse ways.

In principle, the present invention can be applied to all microelectronic areas, but it is preferably applied in memory element technology in the context of feature sizes below 110 nm.

1. A fabrication method for an integrated circuit structure comprising the steps of:
forming a layer stack (5, 6′, 7′, 8′) by sequentially depositing
i) a polysilicon layer (5) on a dielectric layer (9);
ii) a contact layer (6′) composed of Ti on the polysilicon layer (5);
iii) a barrier layer (7′) composed of WN on the contact layer (6′); and
iv) a metal layer (8′) composed of W on the barrier layer (7′);
wherein steps iii) and iv) are carried out as PVD steps using krypton and/or xenon as sputtering gas; and
annealing the layer stack (5, 6′, 7′, 8′) in a thermal step in the temperature range of between 600 and 950° C.

2. The method of claim 1, wherein the layer stack (5, 6′, 7′, 8′) is a gate electrode layer stack.

3. The method as claimed in claim 1,
wherein
steps iii) and iv) are carried out in situ, and in step iii) nitrogen is used as sputtering gas in addition to krypton and/or xenon.

4. The method as claimed in claim 1 or 2,
wherein
the layer stack (5, 6′, 7′, 8′) is patterned prior to annealing.

5. The method as claimed in claim 2,
wherein
a lowering of the resistance of the transistor gate structure of between 35 and 55% is obtained by the annealing.

6. The method as claimed in one of the preceding claims,
wherein
step ii) is carried out as a PVD step using argon as sputtering gas.

7. The method as claimed in one of the preceding claims,
wherein
an insulation cap (4) and insulating sidewall layers (3) are formed prior to annealing.

8. The method as claimed in one of the preceding claims,
wherein
the contact layer (6′) composed of Ti is converted into a TiN layer during annealing.

9. The method as claimed in one of the preceding claims,
wherein
an argon/hydrogen mixture and/or forming gas is used as annealing gas.
